(19) United States
(12) Patent Application Publication
(10) Pub. No.: US 2025/0062694 A1
(43) Pub. Date: Feb. 20, 2025

(54) DRIVING CIRCUIT AND MULTIPHASE VOLTAGE REGULATOR

(71) Applicant: Monolithic Power Systems, Inc., Kirkland, WA (US)

(72) Inventors: Yi-Peng Lin, New Taipei City (TW); Shih-An Wang, Taoyuan City (TW)

(21) Appl. No.: 18/806,689

(22) Filed: Aug. 15, 2024

(30) Foreign Application Priority Data
Aug. 16, 2023 (TW) 112130832
Aug. 12, 2024 (TW) 113130196

(51) Int. Cl. H02M 3/158; H02M 1/088; H03K 17/08; H03K 17/082

(52) U.S. Cl. CPC H02M 3/1586; H02M 1/088; H03K 17/0822; H03K 2017/0806

(57) ABSTRACT

A driving circuit is provided. The driving circuit includes a first switch, a second switch, a temperature sensing circuit, and a control circuit. The first terminal of the first switch is configured to receive an input voltage. The first terminal of the second switch is coupled to the second terminal of the first switch, and the second terminal of the second switch is coupled to a ground. The temperature sensing circuit is configured to sense a temperature indicating signal. The control circuit is configured to receive a PWM control signal and the temperature indicating signal and provide an adjusted PWM control signal according to the PWM control signal and the temperature indicating signal. An on-time of the adjusted PWM control signal is different from an on-time of the PWM control signal.

### CROSS-REFERENCE TO RELATED APPLICATIONS

This application claims priority to and the benefit of Taiwan Patent Application No. 112130832, filed on Aug. 16, 2023, and Taiwan Patent Application No. 113130196, filed on Aug. 12, 2024, which are incorporated herein by reference in its entirety.

### TECHNICAL FIELD

The present disclosure relates generally to electronic circuits, and more particularly but not exclusively to a driving circuit for a multiphase voltage regulator.

### BACKGROUND OF THE INVENTION

Interleaved multiphase voltage regulator is widely used in various large-current applications, e.g., processor, memory, etc. By coupling the power circuits of multiple phases in parallel and using a controller to provide a pulse-width modulation (PWM) signal to each phase, the multiphase voltage regulator may control the operation of each phase to provide the output current corresponding to the load, or when the load requires a large current, N phases that are coupled in parallel may be switched on and off synchronously, and the ripples in the input and the output may be reduced.

However, the power circuit of each phase may have different temperature due to different operation according to different PWM control signal, different circuit layout, or various parameters of each phase. For the efficiency of the whole system, achieving thermal balance between the power circuits of different phases is an important question as well. One way to solve it is that the power circuit of each phase reports its temperature information back to the controller, and the controller adjusts the current of each phase by controlling the PWM control signal to control the temperature of each phase. However, in the situation where each phase includes multiple power circuits coupled in parallel, the temperature of the different power circuits in the same phase cannot be adjusted by controlling the PWM control signal.

### SUMMARY OF THE INVENTION

According to an embodiment of the present disclosure, a driving circuit is provided. The driving circuit includes a first switch, a second switch, a temperature sensing circuit, and a control circuit. The first switch has a first terminal, a second terminal, and a control terminal. The first terminal of the first switch is configured to receive an input voltage. The second switch has a first terminal, a second terminal, and a control terminal. The first terminal of the second switch is coupled to the second terminal of the first switch, and the second terminal of the second switch is coupled to a ground. The temperature sensing circuit is configured to sense a temperature indicating signal. The control circuit is configured to receive a PWM control signal and the temperature indicating signal, and provide an adjusted PWM control signal to turn on or turn off the first switch and the second switch according to the PWM control signal and the temperature indicating signal. An on-time of the adjusted PWM control signal is different from an on-time of the PWM control signal.

According to another embodiment of the present disclosure, a multiphase voltage regulator is provided. The multiphase voltage regulator includes multiple driving circuits and a controller. Each of the driving circuits includes an input pin configured to receive an input voltage, a PWM pin configured to receive a PWM control signal, a temperature pin configured to provide a temperature indicating signal, and a switching pin configured to provide an adjusted PWM control signal. The temperature pins of the driving circuits are coupled to each other. The controller includes multiple PWM control pins and a temperature reporting pin. The PWM control pins are coupled to the corresponding PWM pins of the driving circuits to provide the corresponding PWM control signals, the temperature reporting pin is coupled to the temperature pins of the driving circuits and is configured to send a temperature reporting command to the driving circuits and receive temperature information from the driving circuits. An on-time of the adjusted PWM control signal of one of the driving circuits is different from an on-time of the PWM control signal of one of the driving circuits.

According to yet another embodiment of the present disclosure, a driving circuit is provided. The driving circuit includes an input pin, a PWM pin, a temperature pin, a switching pin, a first switch, a second switch, a temperature sensing circuit, and a control circuit. The input pin is configured to receive an input voltage. The PWM pin is configured to receive a PWM control signal. The temperature pin is configured to provide a temperature indicating signal. The temperature pin is configured to be coupled to a corresponding temperature pin of another driving circuit. The switching pin is configured to provide an adjusted PWM control signal. The first switch has a first terminal, a second terminal, and a control terminal. The first terminal of the first switch is configured to receive the input voltage, and the second terminal of the first switch is coupled to the switching pin. The second switch has a first terminal, a second terminal, and a control terminal. The first terminal of the second switch is coupled to the second terminal of the first switch, and the second terminal of the second switch is coupled to a ground. The temperature sensing circuit is configured to sense the temperature indicating signal. The control circuit is configured to receive the PWM control signal and the temperature indicating signal, and to turn on or turn off the first switch and the second switch according to the PWM control signal and the temperature indicating signal. An on-time of the adjusted PWM control signal is different from an on-time of the PWM control signal.

According to yet another embodiment of the present disclosure, a driving circuit is provided. The driving circuit includes a first switch, a second switch, a temperature sensing circuit, an on-time adjustment circuit, and a control circuit. The first switch has a first terminal, a second terminal, and a control terminal. The first terminal of the first switch is configured to receive an input voltage. The second switch has a first terminal, a second terminal, and a control terminal. The first terminal of the second switch is coupled to the second terminal of the first switch, and the second terminal of the second switch is coupled to a ground. The temperature sensing circuit is configured to sense a temperature indicating signal. The on-time adjustment circuit is configured to provide an on-time adjustment value according to the temperature indicating signal. The control circuit is configured to receive a PWM control signal and the on-time adjustment value and provide an adjusted PWM control signal to turn on or turn off the first switch and the second switch according to the PWM control signal and the on-time adjustment value. An on-time of the adjusted PWM control signal is different from an on-time of the PWM control signal.

According to yet another embodiment of the present disclosure, a multiphase voltage regulator is provided. The multiphase voltage regulator includes multiple driving circuits and a controller. Each of the driving circuits includes an input pin configured to receive an input voltage, a PWM pin configured to receive a PWM control signal, a temperature pin configured to provide a temperature indicating signal, and a switching pin configured to provide an adjusted PWM control signal. The temperature pins of the driving circuits are coupled to each other. The controller includes multiple PWM control pins. The PWM control pins are coupled to the corresponding PWM pins of the driving circuits and are configured to provide the corresponding PWM control signals. An on-time of the adjusted PWM control signal of one of the driving circuits is different from an on-time of the PWM control signal of the one of the driving circuits.

### BRIEF DESCRIPTION OF THE DRAWINGS

The present disclosure can be further understood with reference to following detailed description and appended drawings, wherein like elements are provided with like reference numerals. These drawings are only for illustration purpose, thus may only show part of the devices and are not necessarily drawn to scale.

FIG. 1 is a schematic diagram of a multiphase voltage regulator in accordance with an embodiment of the present disclosure.

FIG. 2 is a schematic diagram of a multiphase voltage regulator in accordance with another embodiment of the present disclosure.

FIG. 3 is a schematic diagram of a temperature reporting network for a multiphase voltage regulator in accordance with an embodiment of the present disclosure.

FIG. 4 is a schematic diagram of an active thermal balance in accordance with an embodiment of the present disclosure.

FIG. 5 is a flow chart of a method for controlling a driving circuit in accordance with an embodiment of the present disclosure.

FIG. 6 is a schematic diagram of a temperature processing module of a controller in accordance with an embodiment of the present disclosure.

FIG. 7 is a timing diagram illustrating identification codes assignment by a multiphase voltage regulator in accordance with an embodiment of the present disclosure.

FIG. 8 is a flow chart of a method for controlling a driving circuit in accordance with another embodiment of the present disclosure.

FIG. 9 is a schematic diagram of a multiphase voltage regulator in accordance with another embodiment of the present disclosure.

FIG. 10 is a schematic diagram of a driving circuit for a multiphase voltage regulator in accordance with an embodiment of the present disclosure.

FIG. 11 is a flow chart of a method for controlling a driving circuit in accordance with another embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”,“right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used include both combinations and sub-combinations of various features described herein as well as variations and modifications thereof. These phrases used herein do not necessarily refer to the same embodiment, although they may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or that the element is indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

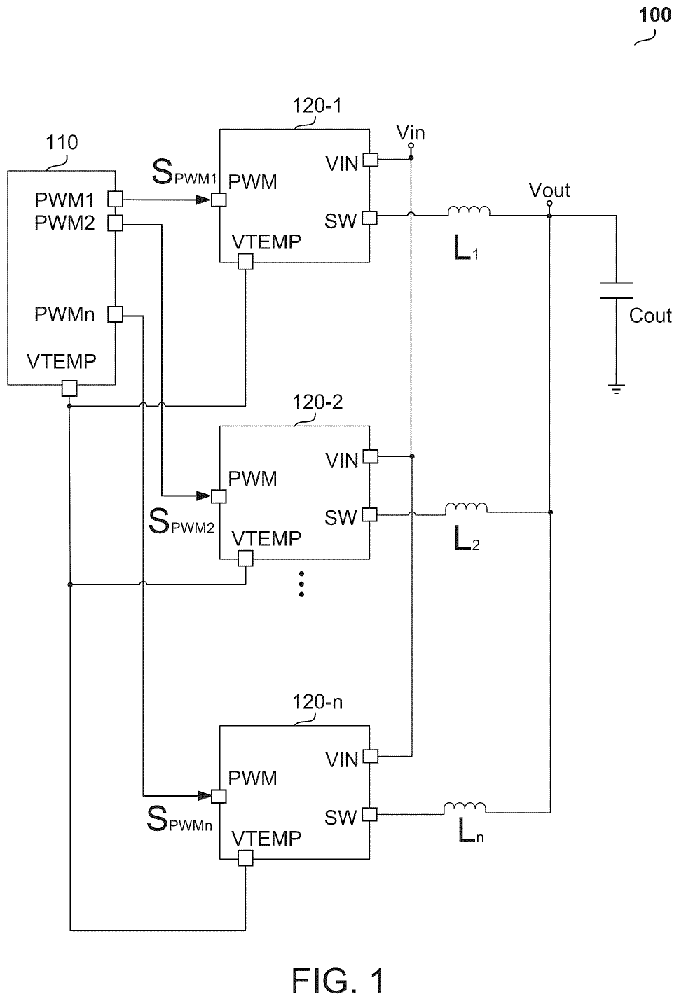

FIG. 1 is a schematic diagram of a multiphase voltage regulator 100 in accordance with an embodiment of the present disclosure. In this embodiment, the multiphase voltage regulator 100 includes a controller 110 and n driving circuits 120-1, 120-2, . . . , 120-n, where n is a positive integer that is greater than or equal to 2. In one embodiment, each of the driving circuits provides one phase of the multiphase voltage regulator 100. In one embodiment, each phase provides a respective output current to a load. The n phases are coupled in parallel and interleaved to reduce current ripples at the input and output to provide a higher output current under heavy load. In another embodiment, the output current of each phase may be adjusted according to the load requirement.

In one embodiment, the controller 110 is an integrated circuit (IC). As shown in FIG. 1, the controller 110 includes PWM control pins (e.g., PWM1, PWM2, . . . , PWMn) and a temperature reporting pin VTEMP. The PWM control pins are coupled to the respective PWM pins of the driving circuits and are configured to provide the PWM control signals to control the corresponding driving circuits. In one embodiment, the PWM control pin PWM1 of the controller 110 provides a first phase PWM control signal S_{PWM1} to the driving circuit 120-1, the PWM control pin PWM2 of the controller 110 provides a second phase PWM control signal S_{PWM2} to the driving circuit 120-2, and so on. In another embodiment, a PWM control pin may provide a PWM control signal with the same phase to multiple driving circuits. As shown in FIG. 1, the temperature reporting pin VTEMP of the controller 110 is coupled to the temperature pins VTEMP of all driving circuits and is configured to send a temperature reporting command to the driving circuits and receive temperature information from the driving circuits.

In one embodiment, the controller 110 detects a feedback signal and adjusts the PWM control signals to control the operation of the driving circuits accordingly. The feedback signal is, for example, the output voltage or the output current. In another embodiment, the multiphase voltage regulator 100 further includes a feedback circuit (not shown in FIG. 1). The feedback circuit is configured to provide the feedback signal to the controller 110. The controller 110 generates the PWM control signals according to the received feedback signal to control the operation of the driving circuits. In yet another embodiment, by receiving the feedback signal from the driving circuits, the controller 110 may adjust the PWM control signals provided to the driving circuits correspondingly. In some embodiments, the driving circuits send data back to the controller 110, and the controller 110 adjusts the PWM control signals provided to the driving circuits 120 according to the data sent from the driving circuits 120. For example, the data may include temperature information, current signals, voltage signals, error signal and/or other detected signals.

In one embodiment, each of the driving circuits 120-1, 120-1, . . . , 120-n is an IC. Each driving circuit includes an input pin VIN, a PWM pin, a temperature pin VTEMP, and a switching pin SW. The input pins VIN of the driving circuits are coupled to a voltage source to receive an input voltage Vin. The PWM pin of each driving circuit is configured to receive the respective PWM control signal (e.g., S_{PWM1}, S_{PWM2}, S_{PWMn}). The temperature pin VTEMP of each driving circuit is configured to provide a temperature indicating signal. The switching pin SW of each driving circuit is configured to provide an adjusted PWM control signal. In addition, the switching pin SW of each driving circuit is coupled to a voltage output node Vout through the inductors L₁, L₂, . . . , Lₙ to provide the output voltage to the load. An output capacitor Cout is coupled to the output voltage (e.g., across the voltage output node Vout and the ground) to filter the output voltage signal.

In one embodiment, the controller 110 further includes a temperature processing module (not shown in FIG. 1). The temperature processing module is configured to send a temperature reporting command to the temperature reporting pin VTEMP of the controller 110 to record the temperature indicating signal in a register. In one embodiment, the controller sends the temperature reporting command to all driving ICs at the same time to record the highest temperature T_max among all driving ICs. In another embodiment, the controller 110 records each of the temperatures of each driving IC, T_phase 1 to T phase n.

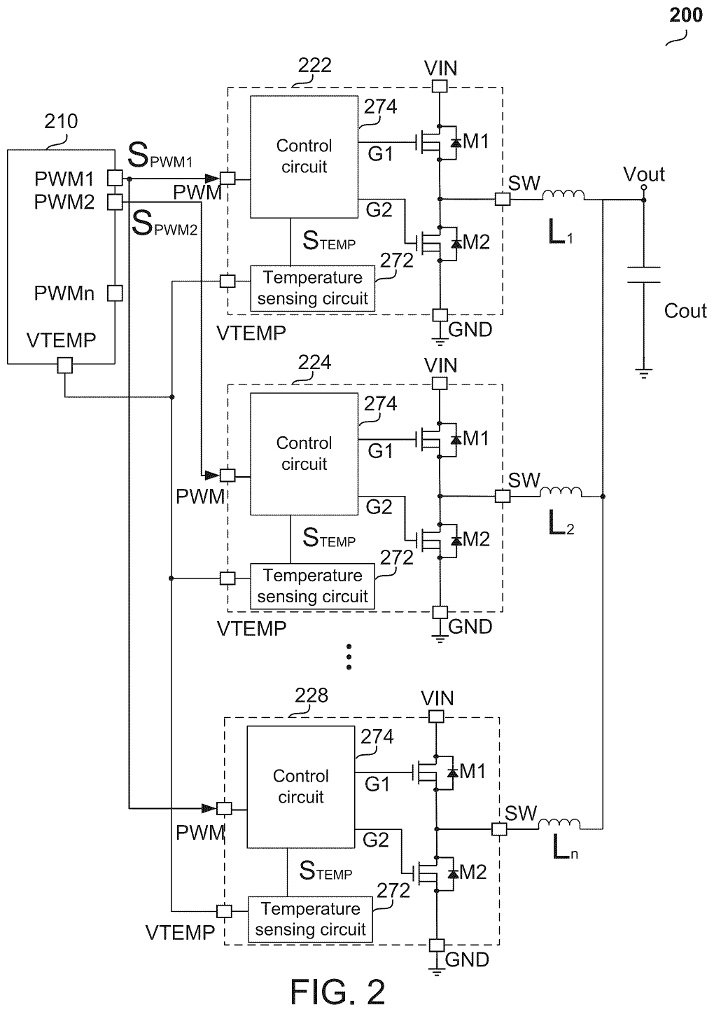

FIG. 2 is a schematic diagram of a multiphase voltage regulator 200 in accordance with another embodiment of the present disclosure. In this embodiment, the PWM control pin PWM1 of the controller 210 is configured to provide the same PWM control signal S_{PWM1} to multiple driving ICs (e.g., 222 and 228), and the PWM control pin PWM2 of the controller 210 is configured to provide another PWM control signal S_{PWM2} to the driving IC 224.

In one embodiment, each driving circuit includes a switch M1, a switch M2, a temperature sensing circuit 272, and a control circuit 274. The first terminal of the switch M1 is coupled to the voltage source, and the second terminal of the switch M1 is coupled to the first terminal of the switch M2. The second terminal of the switch M2 is coupled to the ground via the pin GND. The temperature sensing circuit 272 is configured to sense a temperature indicating signal S_{TEMP}. The temperature indicating signal S_{TEMP} is configured to indicate the temperature of the corresponding driving IC. The control circuit 274 is configured to generate driving signals G1 and G2 to turn on and/or turn off the switches M1 and M2.

In this embodiment, although the driving ICs 222 and 228 receive the same PWM control signal, these two ICs may have different temperatures. To achieve thermal balance between the driving ICs that receive the PWM control signal with the same phase, the control circuit 274 receives the PWM control signal from the controller 210 via the pin PWM and receives the temperature indicating signal S_{TEMP} from the temperature sensing circuit 272, and provides the adjusted PWM control signal at the switching pin SW according to the PWM control signal and the temperature indicating signal S_{TEMP}. In another embodiment, the adjusted PWM control signal is provided to the switches M1 and M2 to turn on and/or turn off the switches M1 and M2. In other words, although the driving ICs 222 and 228 receive the PWM control signal with the same phase, the on-time of the driving IC 222 and the on-time of the driving IC 228 will be adjusted according to their temperatures respectively and thus be different from each other. That is, the switches in the driving ICs 222 and 228 will not be turned on or off synchronously.

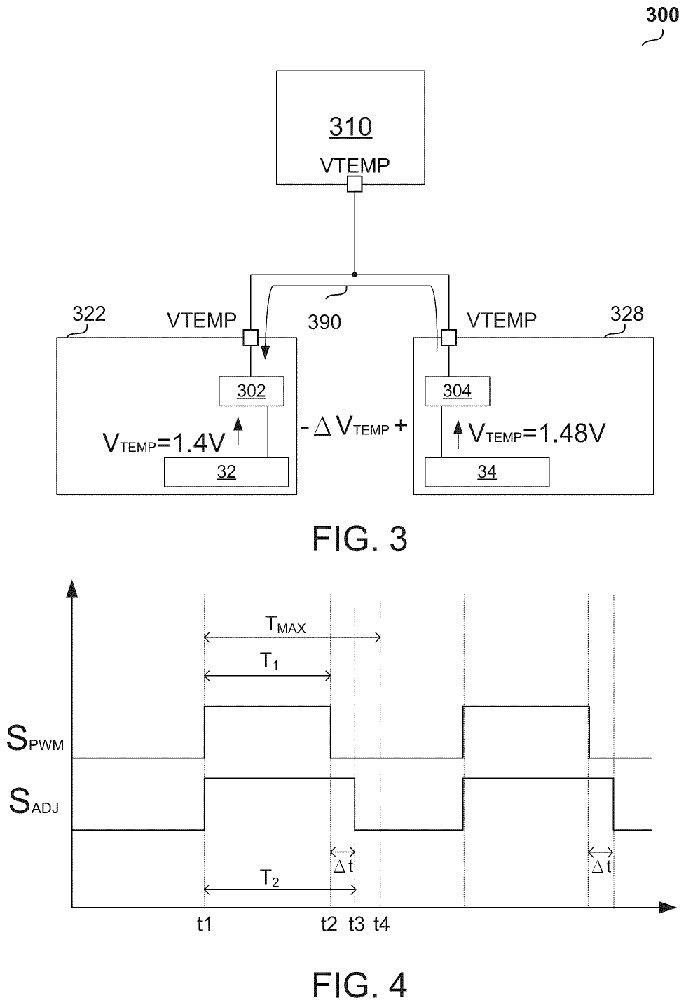

Next, please refer to FIGS. 3 and 4 that illustrate working principles of active thermal balance. FIG. 3 is a schematic diagram of a temperature reporting network for a multiphase voltage regulator 300 in accordance with an embodiment of the present disclosure. As shown in FIG. 3, the pins VTEMP of the driving ICs 322 and 328 are both coupled to the pin VTEMP of the controller 310. For example, the temperature indicating signal sensed by the temperature sensing circuit 32 of the driving IC 322 is represented as the voltage V_{TEMP} of 1.4V, and the temperature indicating signal sensed by the temperature sensing circuit 34 of the driving IC 328 is represented as the voltage V_{TEMP} of 1.48V. In one embodiment, the voltage V_{TEMP} is proportional to the junction temperature of the driving IC. That is, the temperature of the driving IC 328 is higher than the driving IC 322. In such cases, there is a voltage difference ΔV_{TEMP} between the temperature indicating signal of the temperature sensing circuit 32 and the temperature indicating signal of the temperature sensing circuit 34, and thus a current flows between the two driving ICs through the coupled pins VTEMP, for example, a current flows from the driving IC 328 to the driving IC 322 (an arrow 390 as shown in FIG. 3). Therefore, each driving IC determines whether it has a higher or lower temperature compared with other driving ICs by detecting whether it sinks current from other driving IC or sources current to other ICs. For example, the driving ICs 322 and 328 includes current direction detection units 302 and 304 configured to determine whether the pin VTEMP of the driving IC sinks current from the pin VTEMP other driving IC, or sources current to the pin VTEMP of other driving IC. In one implementation, each of the current direction detection units 302 and 304 includes a resistor. The resistor is coupled in series with the temperature sensing circuits 32/34 and the pin VTEMP and is configured to determine the direction of the current according to the voltage across the two terminals of the resistor. It should be understood that, in this embodiment, although only two driving ICs are illustrated, the multiphase voltage regulator 300 may further include more driving ICs, and the pins VTEMP of all driving ICs are coupled to the pin VTEMP of the controller 310.

FIG. 4 is a schematic diagram of an active thermal balance in accordance with an embodiment of the present disclosure. In this embodiment, when it is determined that the driving IC 322 has a lower temperature, the control circuit of the driving IC 322 extends the on-time of the PWM control signal SPWM to provide an adjusted PWM control signal S_{ADJ}. For example, when the on-time of the PWM control signal S_{PWM} provided by the controller 310 is T₁=t2-t1, the driving IC 322 with lower temperature will operate with a longer on-time that equals T₃=t3-t1 to achieve thermal balance. The adjustment value Δt as shown in FIG. 4 may be adjusted according to the temperature of the driving IC. In one embodiment, the on-time of the PWM control signal has a maximum. For example, the on-time should not exceed T_{MAX}=t4-t1. In another embodiment, the on-time of the PWM control signal has a minimum, for example, equal to the on-time T₁ provided by the controller 310. In one embodiment, the difference between the maximum and the minimum of the on-time is, for example, 10 ns. It should be noted that, although in FIG. 4 the rising edges of the PWM control signal SPWM provided by the controller 310 and the adjusted PWM control signal S_{ADJ} are at the same time, in practical applications, there may be a delay between the rising edges of the two signals.

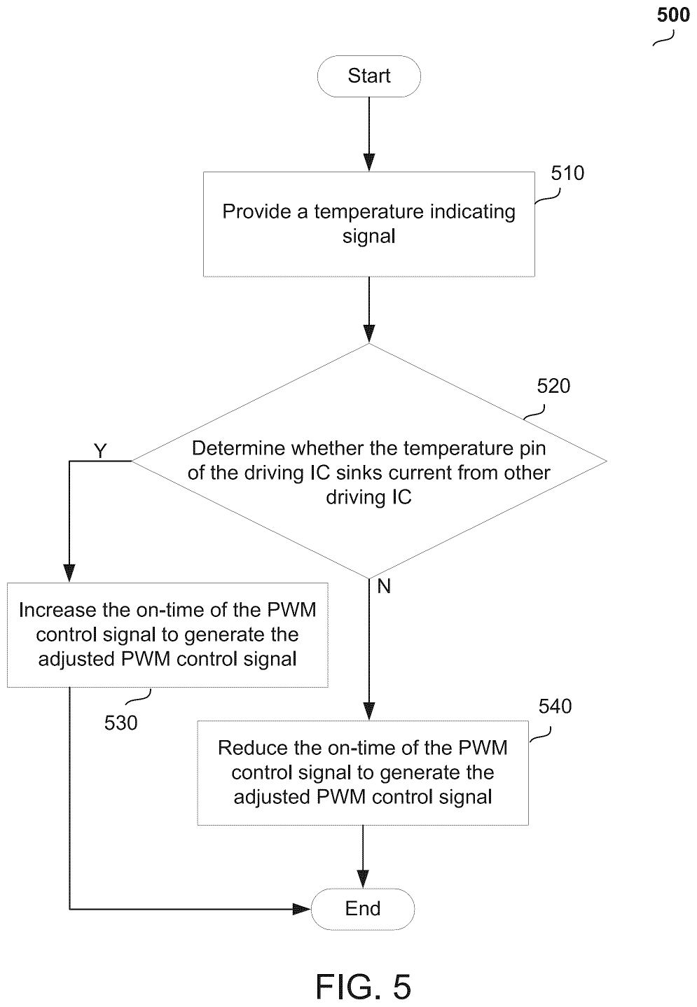

FIG. 5 is a flow chart of a method 500 for controlling a driving circuit in accordance with an embodiment of the present disclosure. The method 500 may be implemented by the driving circuit or driving IC as shown in FIGS. 1, 2, or 3. It should be noted that the method 500 may also be implemented by the elements of the driving circuit, or by other electronic circuits and/or components. The method 500 includes actions 510-540. In action 510, the driving IC provides a temperature indicating signal. In action 520, the driving IC determines whether the temperature pin of the driving IC sinks current from other driving IC. When it is determined that the temperature pin of the driving IC sinks current from the temperature pin of other driving IC, in action 530, the driving IC increases the on-time of the PWM control signal to generate the adjusted PWM control signal. Otherwise, when it is determined that the temperature pin of the driving IC sources current to the temperature pin of other driving IC, in action 540, the driving IC reduces the on-time of the PWM control signal to generate the adjusted PWM control signal.

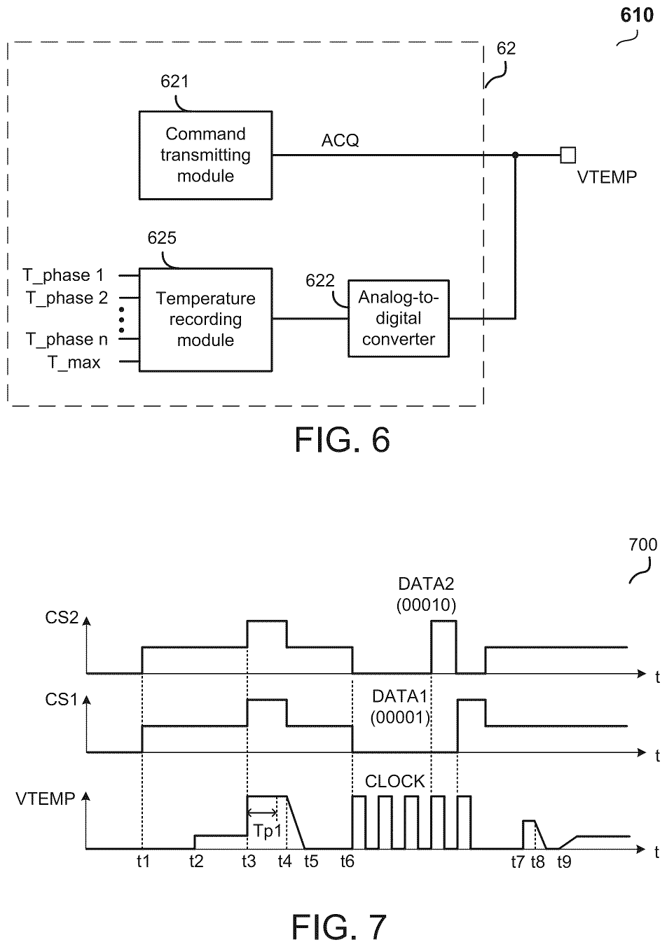

FIG. 6 is a schematic diagram of a temperature processing module 62 of a controller 610 in accordance with an embodiment of the present disclosure. Persons having ordinary skills in the art can understand that the structure of the temperature processing module 62 does not limit to the embodiment as shown in FIG. 6.

In the embodiment as shown in FIG. 6, the temperature processing module 62 includes a command transmitting module 621, a temperature recording module 625, and an analog-to-digital converter (ADC) 622. In one embodiment, after the temperature reporting pin VTEMP of the controller 610 is forced to be at a first state, the command transmitting module 621 sends a temperature reporting command ACQ to the temperature reporting pin VTEMP. For example, the first state includes a high voltage level, maintaining at the high voltage level for a predetermined time (e.g., 10us), or other suitable states. In one embodiment, after the command transmitting module 621 sends the temperature reporting command ACQ, the controller 610 forces the temperature reporting pin VTEMP to be at a second state. For example, the second state includes a middle voltage level or other suitable states that is different from the first state. In one embodiment, the voltage level between a high threshold voltage (e.g., 2V) and a voltage source VCC (e.g., 3.3V) is considered as the high voltage level, the voltage level between zero voltage (0V) and a low threshold voltage (e.g., 1V) is considered as the low voltage level, and the voltage level between the high threshold voltage and the low threshold voltage is considered as the middle voltage level.

In one embodiment, after the command transmitting module 621 sends the temperature reporting command ACQ, the ADC 622 senses the temperature information (e.g., VTEMP). The temperature information VTEMP is converted to a digital signal and provided to the temperature recording module 625 through the ADC 622. The temperature recording module 625 records the digital signal as the temperature signal T_max or one of the phase temperature signals T_phase 1 to T_phase n.

In some embodiments, each driving IC has an identification code Id, such that the driving ICs may be distinguished from each other without adding an extra pin. By doing so, the controller may ask a specific driving IC to report its information (e.g., report the temperature of the driving IC). Accordingly, the controller 101 may obtain the temperature of each driving IC and further perform active thermal balance, individual health check, and other functions.

FIG. 7 is a timing diagram 700 illustrating identification codes assignment by a multiphase voltage regulator in accordance with an embodiment of the present disclosure. As shown in FIG. 7, CS2 represents a voltage signal at the multiplex pin CS2 of the controller, CS1 represents a voltage signal at the multiplex pin CS1 of the controller, and VTEMP represents a voltage signal at the temperature reporting pin VTEMP of the controller. In some embodiments, the controller has n multiplex pins CS1-CSn that are coupled to the current sensing pins CS of the n driving ICs respectively. Each driving IC may further include a current sensing circuit (not shown in figures) to sense the current signal and send the current signal back to the controller through the current sensing pin CS. In one embodiment, the current signal indicates the current flowing through the inductor. In another embodiment, the current signal indicates the output current.

As shown in FIG. 7, after the controller is ready, at time t1, the multiplex pins CS1 and CS2 are forced by the controller to be at the middle voltage level. At time t2, all driving ICs are ready, and the voltage at the temperature reporting pin VTEMP of the controller are provided by all of the driving ICs. At time t3, the controller forces the temperature reporting pin VTEMP and the multiplex pins CS1 and CS2 to be at the first state (e.g., maintaining at the high voltage level for at least a time period Tp1) for initial identification codes assignment. For example, the time period Tp1 is equal to 10us. In one embodiment, after the time period Tp1, the controller keeps the temperature reporting pin VTEMP at a high-impedance state, and all driving ICs temporarily stops reporting their information via the temperature reporting pin VTEMP of the controller. During time t4 to time t5, if there is no malfunction, the voltage at the temperature reporting pin VTEMP of the controller is pulled down. During time t6 to time t7, the controller sends a clock signal CLOCK through the temperature reporting pin VTEMP, sends a data signal DATA1 to the current sensing pin CS of the first driving IC through the multiplex pin CS1, and sends a data signal DATA2 to the current sensing pin CS of the second driving IC through the multiplex pin CS2.

In the embodiment as shown in FIG. 7, the clock signal CLOCK includes 5 pulses. In other embodiments, the clock signal CLOCK may be greater than 5 pulses. In another embodiments, the clock signal CLOCK may be less than 5 pulses. The first driving IC obtains the identification code 00001 according to the data signal DATA1 and the clock signal CLOCK, and the second driving IC obtains the identification code 00010 according to the data signal DATA2 and the clock signal CLOCK. After the controller finishes sending the clock signal CLOCK and the data signals DATA1 and DATA2, at time t7, the controller forces the temperature reporting pin VTEMP and the multiplex pins CS1 and CS2 to be at the second state, for example, maintaining at the middle voltage level. Then, at time t8, the controller releases the forcing control of the temperature reporting pin VTEMP and the multiplex pins CS1 and CS2. During time t8 to time t9, if there is no malfunction, the voltage at the temperature reporting pin VTEMP of the controller is pulled down. At time t9, the voltage at the temperature reporting pin VTEMP of the controller 101 is provided by all driving ICs, the multiplex pin CS1 receives the current sensing signal of the first driving IC, and the multiplex pin CS2 receives the current sensing signal of the second driving IC.

In one embodiment, when the temperature pin VTEMP of the driving IC receives the temperature reporting command ACQ from the temperature reporting pin VTEMP of the controller, the control circuit of the driving IC determines whether the temperature reporting command ACQ includes the identification code Id that matches the driving IC. If the control circuit determines that the temperature reporting command ACQ includes the identification code Id that matches the driving IC, the control circuit of the driving IC sends the temperature information of the driving IC to the temperature reporting pin VTEMP of the controller through the temperature pin VTEMP of the driving IC.

In one example, the temperature reporting command ACQ may select a specific driving IC to report information. For example, the specific driving IC reports information through the temperature reporting pin VTEMP of the controller, and other driving ICs stops reporting information. In one implementation, the temperature reporting command ACQ may include one or more pulses. When the number of pulses of the temperature reporting command ACQ matches the identification code Id of one of the driving ICs (for example, 3 pulses represents the driving IC having the assigned identification code Id_3), the third driving IC reports information to the controller. In another embodiment, when the temperature reporting command ACQ matches a default identification code Id_all (for example, 0 pulse matches the default identification code Id_all and represents all driving ICs), all driving ICs report their information to the controller.

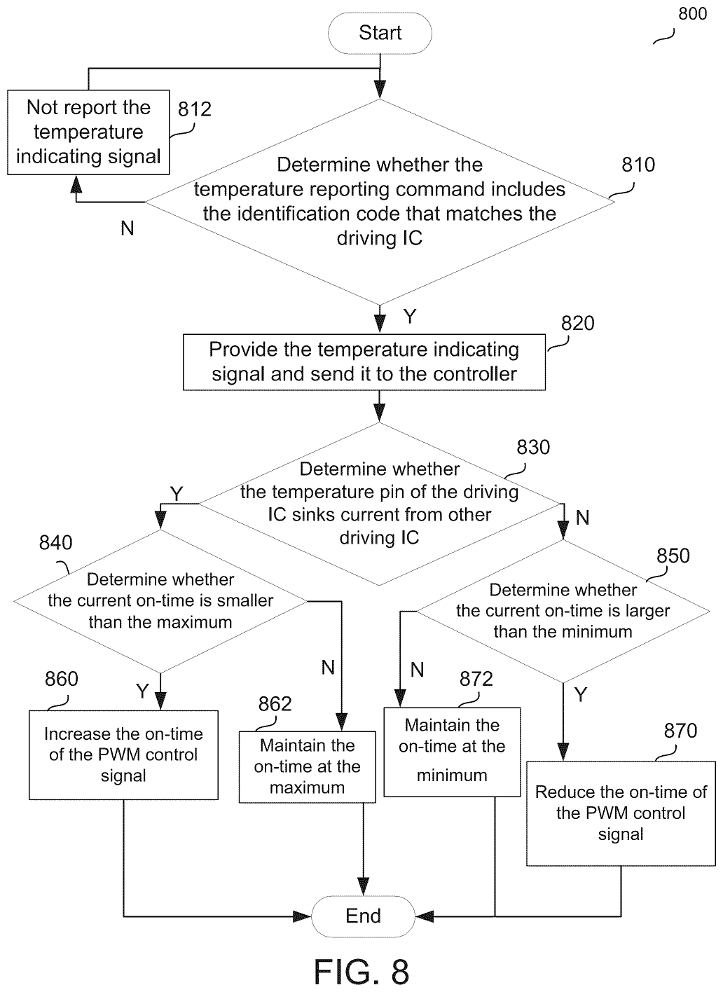

FIG. 8 is a flow chart of a method 800 for controlling a driving circuit in accordance with another embodiment of the present disclosure. The method 800 may be performed by the driving circuit or driving IC as shown in FIGS. 1, 2, or 3. It should be noted that the method 800 may also be performed by the elements of the driving circuit, or by other electronic circuits and/or components. The method 800 includes the following actions. In this embodiment, the active thermal balance among the driving ICs is performed when each driving IC reports its temperature. At action 810, the driving IC determines whether the temperature reporting command received from the controller includes the identification code that matches the driving IC itself. For example, if the temperature reporting command matches the identification code of the driving IC (for example, 3 pulses represents the driving IC having the assigned identification code Id_3), the third driving IC that corresponds to the identification code Id_3 performs action 820 to provide the temperature indicating signal and send it back to the controller. Correspondingly, the temperature reporting command does not match the identification codes of other driving ICs, and the other driving ICs perform action 812, i.e., not reporting the temperature indicating signal to the controller. In one embodiment, when the temperature reporting command matches the default identification code Id_all, all driving ICs report their information to the controller, and the active thermal balance is not performed in the situation.

Next, at action 830, the driving IC determines whether the temperature pin of the driving IC sinks current from other driving IC. If the driving IC determines that its temperature pin sinks current from the temperature pin of other driving IC, it shows that the driving IC has a lower temperature, and the driving IC then performs the action 840, i.e., determining whether the current on-time is smaller than the maximum. If yes, the driving IC performs the action 860, i.e., increasing the on-time of the PWM control signal. If the current on-time is equal to the maximum, the driving IC performs the action 862, i.e., maintaining the on-time at the maximum.

On the other hand, if the driving IC determines that its temperature pin sources current to the temperature pin of other driving IC, it shows that the driving IC has a higher temperature. Then, the driving IC performs the action 850, i.e., determining whether the current on-time is larger than the minimum. If yes, the driving IC performs the action 870, i.e., reducing the on-time of the PWM control signal. If the current on-time is equal to the minimum, the driving IC performs the action 872, i.e., maintaining the on-time at the minimum.

In one embodiment, the difference between the maximum on-time and the minimum on-time is, for example, 10 ns. In one example, 10 ns may be divided into multiple steps for adjusting the on-time. For example, one step may be 0.5 ns, and the on-time may be increased or decreased by 0.5 ns each time. Specifically, the action 830 is performed every period of time, and the adjustment of the on-time performed in the action 860 or 870 is only 0.5 ns. When the adjustment of the on-time is finished (i.e., the action 860 or 870 is performed), after a period of time, the action 830 is performed repeatedly, i.e., determining again whether there is still imbalance between the temperature of the driving ICs (i.e., one driving IC sinks current from or sources current to another driving IC). If yes, then the on-time is adjusted again to be increased or decreased by 0.5 ns. During each adjustment, if the on-time has reached the maximum or the minimum, then the on-time will not be adjusted, as shown by the action 862 or 872, but after a period of time, the action 830 will be performed again to determine whether the on-time should be adjusted. In one embodiment, the action 830 further includes determining whether a thermal balance has been reached, i.e., no driving IC sinks current from or sources current to another driving IC. In this situation, the on-time will not be adjusted, and the action 830 will be performed again after a period of time.

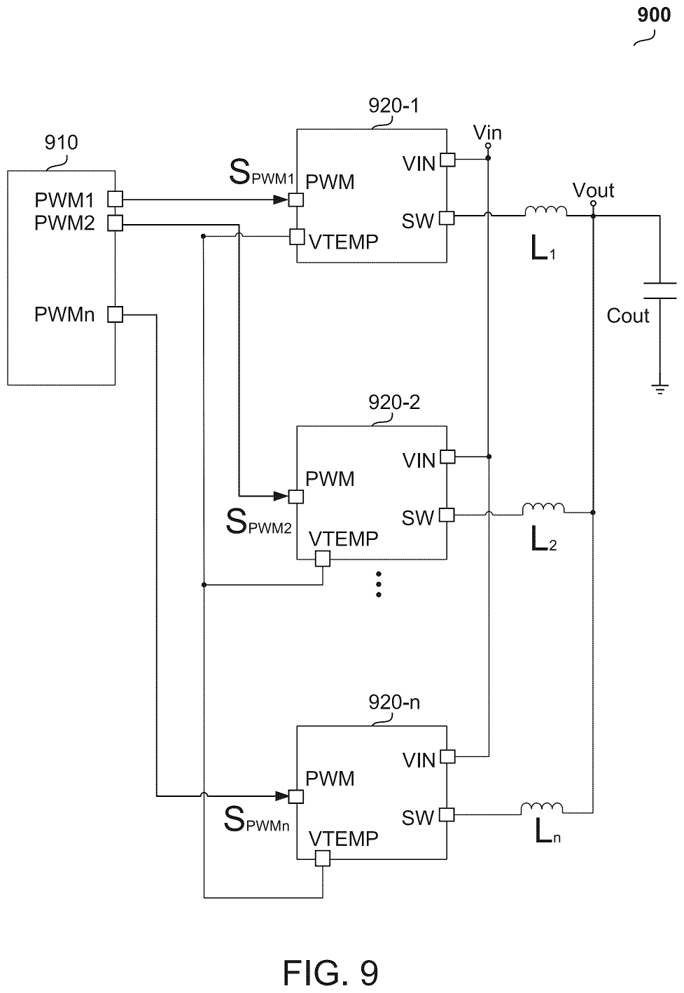

FIG. 9 is a schematic diagram of a multiphase voltage regulator 900 in accordance with another embodiment of the present disclosure. In this embodiment, the multiphase voltage regulator 900 includes a controller 910 and n driving circuits 920-1, 920-2, . . . , 920-n, and n is a positive integer that is larger than or equal to 2. In this embodiment, thermal balance may be performed dynamically without reporting the temperature back to the controller. Specifically, the controller 910 does not include the temperature processing module or the temperature reporting pin VTEMP. In this embodiment, the controller 910 does not send the temperature reporting command to the driving circuits either. The driving circuits do not send the temperature indicating signals back to the controller 910. In other words, the temperature pins VTEMP of the driving circuits are not coupled to the controller 910. All temperature pins VTEMP of the driving circuits are coupled together to achieve thermal balance.

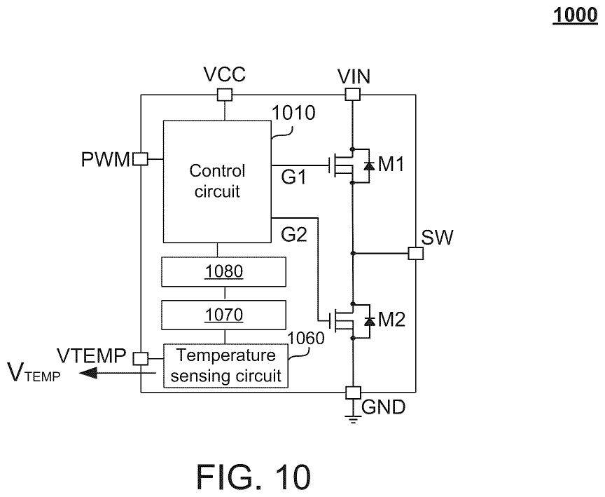

FIG. 10 is a schematic diagram of a driving circuit 1000 for a multiphase voltage regulator 900 in accordance with an embodiment of the present disclosure. In one embodiment, the driving circuit 1000 is an IC. As shown in FIG. 10, the temperature sensing circuit 1060 is configured to generate the temperature indicating signal (e.g., a voltage signal V_{TEMP}) and provide the temperature indicating signal at the temperature pin VTEMP. The on-time adjustment circuit 1080 is configured to provide an on-time adjustment value (e.g., Δt as shown in FIG. 4) to the control circuit 1010 according to the temperature indicating signal. The control circuit 1010 is configured to receive a PWM control signal from the pin PWM and receive the on-time adjustment value to provide an adjusted PWM control signal at the switching pin SW to turn on and/or turn off the switches M1 and M2. The adjusted PWM control signal (e.g., S_{ADJ} as shown in FIG. 4) and the PWM control signal (e.g., S_{PWM} as shown in FIG. 4) have different on-time. In one implementation, when the temperature of the driving IC is larger than the temperature of another driving IC, the on-time adjustment circuit 1080 of the driving IC reduces the on-time adjustment value Δt, e.g., reduce by 0.5 ns. In another implementation, when the temperature of the driving IC is smaller than the temperature of another driving IC, the on-time adjustment circuit 1080 of the driving IC increases the on-time adjustment value Δt, e.g., increase by 0.5 ns. The active thermal balance of each of the driving ICs may be performed without relying on the temperature report mechanism of the controller. In other words, each driving IC may adjust its on-time by itself and does not have to report its temperature information to the controller 910 to adjust its on-time according to the PWM control signal adjusted by the controller 910. In one implementation, the driving IC may perform automatic on-time adjustment periodically. For example, the driving IC may automatically adjust (e.g., increase, decrease, or maintain) its on-time according to its temperature in every period of the PWM control signal.

In one embodiment, the driving circuit 1000 further includes a current direction detection unit 1070 configured to detect that the temperature pin VTEMP of the driving IC sources current to the coupled temperature pin VTEMP of another driving IC, or that the temperature pin VTEMP of the driving IC sinks current from the coupled temperature pin VTEMP of another driving IC. When the temperature pin VTEMP of the driving IC sources current to the coupled temperature pin VTEMP of another driving IC, the on-time adjustment circuit 1080 of the driving IC reduces the on-time adjustment value Δt. When the temperature pin VTEMP of the driving IC sinks current from the coupled temperature pin VTEMP of another driving IC, the on-time adjustment circuit 1080 of the driving IC increases the on-time adjustment value Δt.

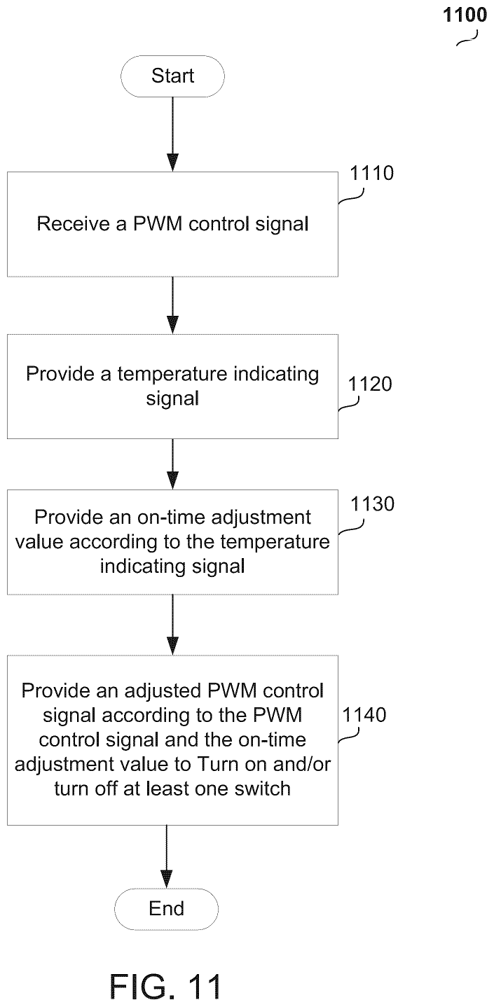

FIG. 11 is a flow chart of a method 1100 for controlling a driving circuit in accordance with another embodiment of the present disclosure. The method 800 may be performed by the driving circuit or driving IC as shown in FIGS. 1, 2, 3, 9, or 10. It should be noted that the method 1100 may also be performed by the elements of the driving circuit, or by other electronic components. The method 1100 includes the following actions. At action 1110, the driving circuit receives a PWM control signal. At action 1120, the driving circuit provides a temperature indicating signal. At action 1130, the driving circuit provides an on-time adjustment value according to the temperature indicating signal. At action 1140, the driving circuit provides an adjusted PWM control signal according to the PWM control signal and the on-time adjustment value to turn on and/or turn off at least one switch. The adjusted PWM control signal and the PWM control signal have different on-time.

It should be noted that the structures and signals of the circuits and their elements described above are merely exemplary, and the present disclosure does not limit thereto. Persons having ordinary skills in the art may design circuits with different structures and adjust the forms of the signals correspondingly according to actual needs to implement the circuits in the present disclosure and achieve the corresponding functions. For example, circuits may be implemented by digital circuits, analog circuits, software, or any combination of above.

While various embodiments have been described above to illustrate the switch circuit of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

What is claimed is:

1. A driving circuit, comprising:
a first switch having a first terminal, a second terminal, and a control terminal, wherein the first terminal of the first switch is configured to receive an input voltage;
a second switch having a first terminal, a second terminal, and a control terminal, wherein the first terminal of the second switch is coupled to the second terminal of the first switch, and the second terminal of the second switch is coupled to a ground;
a temperature sensing circuit configured to sense a temperature indicating signal; and
a control circuit configured to receive a PWM control signal and the temperature indicating signal, and provide an adjusted PWM control signal to turn on or turn off the first switch and the second switch according to the PWM control signal and the temperature indicating signal, wherein an on-time of the adjusted PWM control signal is different from an on-time of the PWM control signal.

2. The driving circuit of claim 1, wherein the driving circuit is an integrated circuit (IC), and the IC further comprises:
an input pin configured to receive the input voltage;
a PWM pin configured to receive the PWM control signal;
a temperature pin configured to provide the temperature indicating signal, wherein the temperature pin is configured to be coupled to the corresponding temperature pin of another IC; and
a switching pin coupled to the second terminal of the first switch and the first terminal of the second switch;
wherein the temperature sensing circuit is further configured to determine that the temperature pin of the IC sinks current from the temperature pin of the another IC, or sources current to the temperature pin of the another IC;
wherein when the temperature sensing circuit indicates that the temperature pin of the IC sinks current from the temperature pin of the another IC, the control circuit is configured to adjust the on-time of the PWM control signal to generate the adjusted PWM control signal.

3. The driving circuit of claim 2, wherein when the temperature sensing circuit indicates that the temperature pin of the IC sinks current from the temperature pin of the another IC, the temperature sensing circuit is further configured to determine whether the on-time of the adjusted PWM control signal is smaller than a maximum;
wherein when the on-time of the adjusted PWM control signal is smaller than the maximum, the control circuit is configured to increase the on-time of the adjusted PWM control signal by an adjustment value to generate the on-time of the adjusted PWM control signal;
wherein when the on-time of the adjusted PWM control signal is not smaller than the maximum, the control circuit is configured to maintain the on-time of the adjusted PWM control signal.

4. The driving circuit of claim 2, wherein when the temperature sensing circuit indicates that the temperature pin of the IC sources current to the temperature pin of the another IC, the temperature sensing circuit is further configured to determine whether the on-time of the adjusted PWM control signal is larger than a minimum;
wherein when the on-time of the adjusted PWM control signal is larger than the minimum, the control circuit is configured to decrease the on-time of the adjusted PWM control signal by an adjustment value to generate the on-time of the adjusted PWM control signal;
wherein when the on-time of the adjusted PWM control signal is not larger than the minimum, the control circuit is configured to maintain the on-time of the adjusted PWM control signal;
wherein the minimum is the same as the on-time of the PWM control signal.

5. The driving circuit of claim 2, wherein the PWM pin of the another IC and the PWM pin of the IC are configured to receive the same PWM control signal;
wherein when a temperature of the IC is higher than a temperature of the another IC, the on-time of the adjusted PWM control signal of the IC is smaller than an on-time of an adjusted PWM control signal of the another IC.

6. The driving circuit of claim 2, wherein the PWM pin of the another IC and the PWM pin of the IC are configured to receive the same PWM control signal;
wherein when a temperature of the IC is higher than a temperature of the another IC, the temperature pin of the IC is configured to source current to the temperature pin of the another IC.

7. The driving circuit of claim 2, wherein the temperature pin of the IC is further configured to be coupled to a temperature reporting pin of a controller;
wherein when the temperature pin of the IC receives a temperature reporting command from the temperature reporting pin of the controller, the control circuit is configured to determine whether the temperature reporting command includes an identification code that matches the IC;
wherein when the control circuit determines that the temperature reporting command includes the identification code that matches the IC, the temperature sensing circuit of the IC sends temperature information of the IC, via the temperature pin, to the temperature reporting pin of the controller;
wherein when the control circuit determines that the temperature reporting command includes the identification code that matches the IC, the control circuit is configured to provide the adjusted PWM control signal.

8. A multiphase voltage regulator, comprising:
multiple driving circuits, wherein each of the driving circuits includes an input pin configured to receive an input voltage, a PWM pin configured to receive a PWM control signal, a temperature pin configured to provide a temperature indicating signal, and a switching pin configured to provide an adjusted PWM control signal, wherein the temperature pins of the driving circuits are coupled to each other; and
a controller including multiple PWM control pins and a temperature reporting pin, wherein the PWM control pins are coupled to the corresponding PWM pins of the driving circuits to provide the corresponding PWM control signals, the temperature reporting pin is coupled to the temperature pins of the driving circuits and is configured to send a temperature reporting command to the driving circuits and receive temperature information from the driving circuits;
wherein an on-time of the adjusted PWM control signal of one of the driving circuits is different from an on-time of the PWM control signal of the one of the driving circuits.

9. The multiphase voltage regulator of claim 8, wherein each of the driving circuit comprises:
a first switch having a first terminal, a second terminal, and a control terminal, wherein the first terminal of the first switch is configured to receive the input voltage;
a second switch having a first terminal, a second terminal, and a control terminal, wherein the first terminal of the second switch is coupled to the second terminal of the first switch, and the second terminal of the second switch is coupled to a ground;
a temperature sensing circuit configured to sense the temperature indicating signal; and
a control circuit configured to receive the PWM control signal and the temperature indicating signal, and provide the adjusted PWM control signal according to the PWM control signal and the temperature indicating signal;
wherein the temperature sensing circuit is further configured to determine that the temperature pin of the driving circuit sinks current from the temperature pin of another driving circuit, or sources current to the temperature pin of the another driving circuit;
wherein when the temperature sensing circuit indicates that the temperature pin of the driving circuit sinks current from the temperature pin of the another driving circuit, the control circuit is configured to adjust the on-time of the PWM control signal to generate the adjusted PWM control signal.

10. The multiphase voltage regulator of claim 9, wherein when the temperature sensing circuit indicates that the temperature pin of the driving circuit sinks current from the temperature pin of the another driving circuit, the temperature sensing circuit is further configured to determine whether the on-time of the adjusted PWM control signal is smaller than a maximum;
wherein when the on-time of the adjusted PWM control signal is smaller than the maximum, the control circuit is configured to increase the on-time of the adjusted PWM control signal by an adjustment value to generate the on-time of the adjusted PWM control signal;
wherein when the on-time of the adjusted PWM control signal is not smaller than the maximum, the control circuit is configured to maintain the on-time of the adjusted PWM control signal.

11. The multiphase voltage regulator of claim 9, wherein when the temperature sensing circuit indicates that the temperature pin of the driving circuit sources current to the temperature pin of the another driving circuit, the temperature sensing circuit is further configured to determine whether the on-time of the adjusted PWM control signal is larger than a minimum;
wherein when the on-time of the adjusted PWM control signal is larger than the minimum, the control circuit is configured to decrease the on-time of the adjusted PWM control signal by an adjustment value to generate the on-time of the adjusted PWM control signal;
wherein when the on-time of the adjusted PWM control signal is not larger than the minimum, the control circuit is configured to maintain the on-time of the adjusted PWM control signal;
wherein the minimum is the same as the on-time of the PWM control signal.

12. The multiphase voltage regulator of claim 9, wherein the PWM pin of the another driving circuit and the PWM pin of the driving circuit are configured to receive the same PWM control signal;
wherein when a temperature of the driving circuit is higher than a temperature of the another driving circuit, the on-time of the adjusted PWM control signal of the driving circuit is smaller than an on-time of an adjusted PWM control signal of the another driving circuit.

13. The multiphase voltage regulator of claim 9, wherein the PWM pin of the another driving circuit and the PWM pin of the driving circuit are configured to receive the same PWM control signal;
wherein when a temperature of the driving circuit is higher than a temperature of the another driving circuit, the temperature pin of the driving circuit is configured to source current to the temperature pin of the another driving circuit.

14. The multiphase voltage regulator of claim 9, wherein when the temperature pin of the driving circuit receives a temperature reporting command from the temperature reporting pin of the controller, the control circuit is configured to determine whether the temperature reporting command includes an identification code that matches the driving circuit;
wherein when the control circuit determines that the temperature reporting command includes the identification code that matches the driving circuit, the temperature sensing circuit of the driving circuit sends the temperature information of the driving circuit, via the temperature pin, to the temperature reporting pin of the controller;
wherein when the control circuit determines that the temperature reporting command includes the identification code that matches the driving circuit, the control circuit is configured to provide the adjusted PWM control signal.

15. A driving circuit, comprising:
an input pin configured to receive an input voltage;
a PWM pin configured to receive a PWM control signal;
a temperature pin configured to provide a temperature indicating signal, wherein the temperature pin is configured to be coupled to a corresponding temperature pin of another driving circuit; and
a switching pin configured to provide an adjusted PWM control signal;
a first switch having a first terminal, a second terminal, and a control terminal, wherein the first terminal of the first switch is configured to receive the input voltage, and the second terminal of the first switch is coupled to the switching pin;
a second switch having a first terminal, a second terminal, and a control terminal, wherein the first terminal of the second switch is coupled to the second terminal of the first switch, and the second terminal of the second switch is coupled to a ground;
a temperature sensing circuit configured to sense the temperature indicating signal; and
a control circuit configured to receive the PWM control signal and the temperature indicating signal, and to turn on or turn off the first switch and the second switch according to the PWM control signal and the temperature indicating signal, wherein an on-time of the adjusted PWM control signal is different from an on-time of the PWM control signal.

16. The driving circuit of claim 15, wherein the temperature sensing circuit is further configured to determine that the temperature pin of the driving circuit sinks current from the temperature pin of the another driving circuit, or sources current to the temperature pin of the another driving circuit;
wherein when the temperature sensing circuit indicates that the temperature pin of the driving circuit sinks current from the temperature pin of the another driving circuit, the control circuit is configured to adjust the on-time of the PWM control signal to generate the adjusted PWM control signal.

17. The driving circuit of claim 16, wherein when the temperature sensing circuit indicates that the temperature pin of the driving circuit sinks current from the temperature pin of the another driving circuit, the temperature sensing circuit is further configured to determine whether the on-time of the adjusted PWM control signal is smaller than a maximum;
wherein when the on-time of the adjusted PWM control signal is smaller than the maximum, the control circuit is configured to increase the on-time of the adjusted PWM control signal by an adjustment value to generate the on-time of the adjusted PWM control signal;
wherein when the on-time of the adjusted PWM control signal is not smaller than the maximum, the control circuit is configured to maintain the on-time of the adjusted PWM control signal.

18. The driving circuit of claim 16, wherein when the temperature sensing circuit indicates that the temperature pin of the driving circuit sources current to the temperature pin of the another driving circuit, the temperature sensing circuit is further configured to determine whether the on-time of the adjusted PWM control signal is larger than a minimum;
wherein when the on-time of the adjusted PWM control signal is larger than the minimum, the control circuit is configured to decrease the on-time of the adjusted PWM control signal by an adjustment value to generate the on-time of the adjusted PWM control signal;
wherein when the on-time of the adjusted PWM control signal is not larger than the minimum, the control circuit is configured to maintain the on-time of the adjusted PWM control signal;
wherein the minimum is the same as the on-time of the PWM control signal.

19. The driving circuit of claim 16, wherein the PWM pin of the another driving circuit and the PWM pin of the driving circuit are configured to receive the same PWM control signal;
wherein when a temperature of the driving circuit is higher than a temperature of the another driving circuit, the on-time of the adjusted PWM control signal of the driving circuit is smaller than an on-time of an adjusted PWM control signal of the another driving circuit.

20. The driving circuit of claim 16, wherein the temperature pin of the driving circuit is further configured to be coupled to a temperature reporting pin of a controller;
wherein when the temperature pin of the driving circuit receives a temperature reporting command from the temperature reporting pin of the controller, the control circuit is configured to determine whether the temperature reporting command includes an identification code that matches the driving circuit;
wherein when the control circuit determines that the temperature reporting command includes the identification code that matches the driving circuit, the temperature sensing circuit of the driving circuit sends temperature information of the driving circuit, via the temperature pin, to the temperature reporting pin of the controller;
wherein when the control circuit determines that the temperature reporting command includes the identification code that matches the driving circuit, the control circuit is configured to provide the adjusted PWM control signal.

21. A driving circuit, comprising:
a first switch having a first terminal, a second terminal, and a control terminal, wherein the first terminal of the first switch is configured to receive an input voltage;
a second switch having a first terminal, a second terminal, and a control terminal, wherein the first terminal of the second switch is coupled to the second terminal of the first switch, and the second terminal of the second switch is coupled to a ground;
a temperature sensing circuit configured to sense a temperature indicating signal;
an on-time adjustment circuit configured to provide an on-time adjustment value according to the temperature indicating signal; and
a control circuit configured to receive a PWM control signal and the on-time adjustment value, and provide an adjusted PWM control signal to turn on or turn off the first switch and the second switch according to the PWM control signal and the on-time adjustment value, wherein an on-time of the adjusted PWM control signal is different from an on-time of the PWM control signal.

22. The driving circuit of claim 21, wherein the driving circuit is an integrated circuit (IC), and the IC further comprises:
an input pin configured to receive the input voltage;
a PWM pin configured to receive the PWM control signal;
a temperature pin configured to provide the temperature indicating signal, wherein the temperature pin is configured to be coupled to a corresponding temperature pin of another IC; and
a switching pin coupled to the second terminal of the first switch and the first terminal of the second switch;
wherein the temperature sensing circuit is further configured to determine that the temperature pin of the IC sinks current from the temperature pin of the another IC, or sources current to the temperature pin of the another IC;
wherein when the temperature sensing circuit indicates that the temperature pin of the IC sinks current from the temperature pin of the another IC, the control circuit is configured to adjust the on-time of the PWM control signal to generate the adjusted PWM control signal.

23. The driving circuit of claim 22, wherein when the temperature sensing circuit indicates that the temperature pin of the IC sinks current from the temperature pin of the another IC, the on-time adjustment circuit is further configured to determine whether the on-time of the adjusted PWM control signal is smaller than a maximum;
wherein when the on-time of the adjusted PWM control signal is smaller than the maximum, the on-time adjustment circuit is configured to increase the on-time adjustment value to generate the on-time of the adjusted PWM control signal;
wherein when the on-time of the adjusted PWM control signal is not smaller than the maximum, the control circuit is configured to maintain the on-time of the adjusted PWM control signal.

24. The driving circuit of claim 22, wherein when the temperature sensing circuit indicates that the temperature pin of the IC sources current to the temperature pin of the another IC, the on-time adjustment circuit is further configured to determine whether the on-time of the adjusted PWM control signal is larger than a minimum;
wherein when the on-time of the adjusted PWM control signal is larger than the minimum, the on-time adjustment circuit is configured to decrease the on-time adjustment value to generate the on-time of the adjusted PWM control signal;
wherein when the on-time of the adjusted PWM control signal is not larger than the minimum, the control circuit is configured to maintain the on-time of the adjusted PWM control signal;
wherein the minimum is the same as the on-time of the PWM control signal.

25. The driving circuit of claim 22, wherein when a temperature of the IC is higher than a temperature of the another IC, the on-time adjustment circuit of the IC is configured to decrease the on-time adjustment value.

26. The driving circuit of claim 22, wherein when a temperature of the IC is lower than a temperature of the another IC, the on-time adjustment circuit of the IC is configured to increase the on-time adjustment value.

27. The driving circuit of claim 22, wherein when a temperature of the IC is higher than a temperature of the another IC, the temperature pin of the IC is configured to source current to the temperature pin of the another IC.

28. The driving circuit of claim 22, wherein when the temperature pin of the IC sources current to the temperature pin of the another IC, the on-time adjustment circuit of the IC is configured to decrease the on-time adjustment value.

29. The driving circuit of claim 22, wherein when the temperature pin of the IC sinks current from the temperature pin of the another IC, the on-time adjustment circuit of the IC is configured to increase the on-time adjustment value.

30. The driving circuit of claim 22, further comprising:
a current direction detection unit configured to detect that the temperature pin of the IC sources current or sinks current;
wherein when the temperature pin of the IC sources current, the on-time adjustment circuit is configured to decrease the on-time adjustment value.

31. The driving circuit of claim 22, further comprising:
a current direction detection unit configured to detect that the temperature pin of the IC sources current or sinks current;
wherein when the temperature pin of the IC sinks current, the on-time adjustment circuit is configured to increase the on-time adjustment value.

32. A multiphase voltage regulator, comprising:
multiple driving circuits, wherein each of the driving circuits includes an input pin configured to receive an input voltage, a PWM pin configured to receive a PWM control signal, a temperature pin configured to provide a temperature indicating signal, and a switching pin configured to provide an adjusted PWM control signal, wherein the temperature pins of the driving circuits are coupled to each other; and
a controller including multiple PWM control pins, wherein the PWM control pins are coupled to the corresponding PWM pins of the driving circuits to provide the corresponding PWM control signals;
wherein an on-time of the adjusted PWM control signal of one of the driving circuits is different from an on-time of the PWM control signal of the one of the driving circuits.

33. The multiphase voltage regulator of claim 32, wherein each of the driving circuit further comprises:
a first switch having a first terminal, a second terminal, and a control terminal, wherein the first terminal of the first switch is configured to receive the input voltage;
a second switch having a first terminal, a second terminal, and a control terminal, wherein the first terminal of the second switch is coupled to the second terminal of the first switch, and the second terminal of the second switch is coupled to a ground;
a temperature sensing circuit configured to sense the temperature indicating signal;
an on-time adjustment circuit configured to provide an on-time adjustment value according to the temperature indicating signal; and
a control circuit configured to receive the PWM control signal and the on-time adjustment value, and provide the adjusted PWM control signal to turn on or turn off the first switch and the second switch according to the PWM control signal and the on-time adjustment value, wherein an on-time of the adjusted PWM control signal is different from an on-time of the PWM control signal;
wherein the temperature sensing circuit is further configured to determine that the temperature pin of the driving circuit sinks current from the temperature pin of another driving circuit of the driving circuits, or sources current to the temperature pin of the another driving circuit;
wherein when the temperature sensing circuit indicates that the temperature pin of the driving circuit sinks current from the temperature pin of the another driving circuit, the control circuit is configured to adjust the on-time of the PWM control signal to generate the adjusted PWM control signal.

34. The multiphase voltage regulator of claim 33, wherein when the temperature sensing circuit indicates that the temperature pin of the driving circuit sinks current from the temperature pin of the another driving circuit, the on-time adjustment circuit is further configured to determine whether the on-time of the adjusted PWM control signal is smaller than a maximum;
wherein when the on-time of the adjusted PWM control signal is smaller than the maximum, the on-time adjustment circuit is configured to increase the on-time adjustment value to generate the on-time of the adjusted PWM control signal;
wherein when the on-time of the adjusted PWM control signal is not smaller than the maximum, the control circuit is configured to maintain the on-time of the adjusted PWM control signal.

35. The multiphase voltage regulator of claim 33, wherein when the temperature sensing circuit indicates that the temperature pin of the driving circuit sources current to the temperature pin of the another driving circuit, the on-time adjustment circuit is further configured to determine whether the on-time of the adjusted PWM control signal is larger than a minimum;
wherein when the on-time of the adjusted PWM control signal is larger than the minimum, the on-time adjustment circuit is configured to decrease the on-time adjustment value to generate the on-time of the adjusted PWM control signal;
wherein when the on-time of the adjusted PWM control signal is not larger than the minimum, the control circuit is configured to maintain the on-time of the adjusted PWM control signal;
wherein the minimum is the same as the on-time of the PWM control signal.
